(19) United States
(12) Patent Application Publication
(10) Pub. No.: US 2026/0215113 A1
(43) Pub. Date: Jul. 23, 2026

(54) DISPLAY PANEL, METHOD OF MANUFACTURING THE SAME, AND ELECTRONIC DEVICE INCLUDING THE SAME

(71) Applicant: Samsung Display Co., Ltd., Yongin-si (KR)

(72) Inventors: KEUMHEE LEE, Yongin-si (KR); HYUNSEONG KANG, Yongin-si (KR); SEUNGRAE KIM, Yongin-si (KR); JOONGEOL KIM, Yongin-si (KR); KANGNAM KIM, Yongin-si (KR); KI-WON KIM, Yongin-si (KR); Sungwon KIM, Yongin-si (KR); JONG-IN KIM, Yongin-si (KR); JI HUN KIM, Yongin-si (KR); KAP SOO YOON, Yongin-si (KR); HYUN SOO LEE, Yongin-si (KR); YOUNGJAE JEON, Yongin-si (KR); Wooseok CHOI, Yongin-si (KR)

(21) Appl. No.: 19/443,992

(22) Filed: Jan. 8, 2026

(30) Foreign Application Priority Data
Jan. 17, 2025 (KR) 10-2025-0007026

(51) Int. Cl. H10K 59/131; H10K 59/12

(52) U.S. Cl. CPC H10K 59/131; H10K 59/1201

(57) ABSTRACT

A display panel includes a base substrate including a display area and a non-display area adjacent to the display area, a circuit layer including a data conductive layer, a protective layer on the data conductive layer, and a via insulating layer on the protective layer and on the base substrate, and a display element layer including a first electrode layer, a pixel defining layer, a light emitting layer, and a second electrode layer and on the circuit layer. The data conductive layer includes a first voltage wiring, and the first electrode layer includes a second voltage wiring connected to the first voltage wiring through a first contact portion provided through the protective layer and the via insulating layer in a contact area in the non-display area.

### CROSS-REFERENCE TO RELATED APPLICATION

The present application claims priority to and the benefit of Korean Patent Application No. 10-2025-0007026, filed on Jan. 17, 2025, in the Korean Intellectual Property Office, the entire disclosure of which is incorporated herein by reference.

### BACKGROUND

Aspects of some embodiments of the present disclosure described herein relate to a display panel, a method of manufacturing the same, and an electronic device including the same.

Multimedia devices such as televisions, mobile phones, tablets, computers, navigation devices, and game consoles may be provided with display panels for displaying images. The display panel may include a plurality of pixels for displaying images, and each of the pixels may include a light emitting element that generates light and a driving element connected to the light emitting element.

The light emitting element and the driving element of the display panel may be formed through lamination of thin films and patterning of the thin films using a mask. Because significant costs may be required for a process of manufacturing the display panel using the mask, it may be desirable to simplify the process of manufacturing the display panel and reduce the number of masks required for manufacturing the display device. Further, it may be desirable to manufacture the display panel having reliability while the process is relatively simplified.

The above information disclosed in this Background section is only for enhancement of understanding of the background and therefore the information discussed in this Background section does not necessarily constitute prior art.

### SUMMARY

Aspects of some embodiments of the present disclosure include a display panel capable of relatively improving process reliability while relatively simplifying a manufacturing process, a method of manufacturing the same, and an electronic device including the same.

According to some embodiments, a display panel includes a base substrate including a display area and a non-display area adjacent to the display area, a circuit layer including a data conductive layer, a protective layer on the data conductive layer, and a via insulating layer on the protective layer and on the base substrate, and a display element layer including a first electrode layer, a pixel defining layer, a light emitting layer, and a second electrode layer and on the circuit layer.

According to some embodiments, the data conductive layer includes a first voltage wiring, and the first electrode layer includes a second voltage wiring connected to the first voltage wiring through a first contact portion provided through the protective layer and the via insulating layer in a contact area positioned in the non-display area.

According to some embodiments, a second contact portion, through which the second voltage wiring is exposed, is provided in the pixel defining layer, and the second electrode layer is connected to the second voltage wiring through the second contact portion, and a width of the second contact portion is smaller than a width of the first contact portion.

According to some embodiments, a method of manufacturing a display panel includes forming a data conductive layer on a base substrate including a display area and a non-display area adjacent to the display area, forming a preliminary protective layer on the data conductive layer, forming a photoresist layer on the preliminary protective layer, forming a photoresist pattern in which a first sub-contact portion is provided in a contact area positioned in the non-display area by patterning the photoresist layer, forming a protective layer in which a second sub-contact portion corresponding to the first sub-contact portion is provided by etching the preliminary protective layer using the photoresist pattern, forming a first electrode layer on a portion of the photoresist pattern, forming a via insulating layer by ashing a portion of the photoresist pattern exposed from the first electrode layer, forming a pixel defining layer on the via insulating layer and the first electrode layer, forming a light emitting layer on the pixel defining layer, and forming a second electrode layer on the light emitting layer.

According to some embodiments, the data conductive layer includes a first voltage wiring, and the first electrode layer includes a second voltage wiring connected to the first voltage wiring through a first contact portion including the first sub-contact portion and the second sub-contact portion. A second contact portion, through which the second voltage wiring is exposed, is provided in the pixel defining layer, and the second electrode layer is connected to the second voltage wiring through the second contact portion, and a width of the second contact portion is smaller than a width of the first contact portion.

According to some embodiments, an electronic device includes a display module including a display panel and a processor that controls driving of the display module.

According to some embodiments, the display panel includes a base substrate including a display area and a non-display area adjacent to the display area, a circuit layer including a data conductive layer, a protective layer on the data conductive layer, and a via insulating layer on the protective layer and on the base substrate, and a display element layer including a first electrode layer, a pixel defining layer, a light emitting layer, and a second electrode layer and on the circuit layer.

According to some embodiments, the data conductive layer includes a first voltage wiring, and the first electrode layer includes a second voltage wiring connected to the first voltage wiring through a first contact portion provided through the protective layer and the via insulating layer in a contact area positioned in the non-display area. A second contact portion, through which the second voltage wiring is exposed, is provided in the pixel defining layer, and the second electrode layer is connected to the second voltage wiring through the second contact portion. A width of the second contact portion is smaller than a width of the first contact portion.

### BRIEF DESCRIPTION OF THE DRAWINGS

The above and other aspects and features of embodiments according to the present disclosure will become more apparent by describing in more detail aspects of some embodiments thereof with reference to the accompanying drawings.

FIG. 1 is a perspective view of the electronic device according to some embodiments of the present disclosure.

FIG. 2 is an exploded perspective view of the electronic device according to some embodiments of the present disclosure.

FIG. 3 is a cross-sectional view of a display module according to some embodiments of the present disclosure.

FIG. 4 is a plan view of a display panel according to some embodiments of the present disclosure.

FIG. 5 is an equivalent circuit diagram of a pixel according to some embodiments of the present disclosure.

FIG. 6 is a cross-sectional view of a portion of a display panel according to some embodiments of the present disclosure.

FIG. 7A is an enlarged plan view of the area A1 illustrated in FIG. 4.

FIG. 7B is a cross-sectional view along the cut line I-I′ illustrated in FIG. 7A according to some embodiments of the present disclosure.

FIG. 7C is a cross-sectional view along the cut line I-I′ illustrated in FIG. 7A according to some embodiments of the present disclosure.

FIG. 8A is an enlarged plan view of the area A2 illustrated in FIG. 4.

FIG. 8B is a cross-sectional view along the cut line II-II′ illustrated in FIG. 8A according to some embodiments of the present disclosure.

FIG. 8C is a cross-sectional view along the cut line II-II′ illustrated in FIG. 8A according to some embodiments of the present disclosure.

FIGS. 9A to 9G are cross-sectional views illustrating some operations in a process of manufacturing a display panel according to some embodiments of the present disclosure.

FIG. 10 is a block diagram of an electronic device according to some embodiments of the present disclosure.

FIG. 11 is a schematic view illustrating electronic devices according to some embodiments.

### DETAILED DESCRIPTION

In the specification, the expression that a first component (or area, layer, part, portion, etc.) is “located on”, “connected with” or “coupled to” a second component means that the first component is directly located on/connected with/coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are used only to distinguish one component, one part, one area, one layer or one portion from another component, another part, another area, another layer or another portion. For example, without departing from the scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Hereinafter, aspects of some embodiments of the present disclosure will be described in more detail with reference to the accompanying drawings.

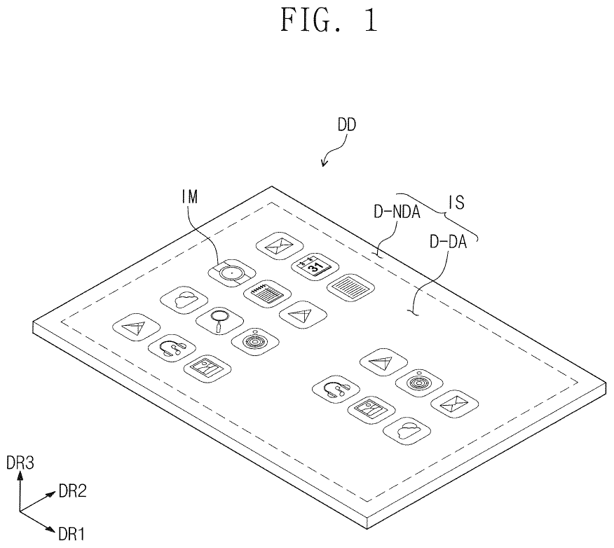

FIG. 1 is a perspective view of an electronic device DD according to some embodiments of the present disclosure.

The electronic device DD may be a display device that is activated by an electric signal and display an image IM. The electronic device DD may include embodiments that provides the image IM to a user. For example, the electronic device DD may be a large-sized device such as a television and an external billboard as well as a small or medium-sized device such as a monitor, a mobile phone, a tablet, a navigation device, and a game console. Meanwhile, the illustrated embodiments of the electronic device DD are illustrative, and the electronic device DD is not limited thereto and the electronic device DD may include any suitable electronic device connected to or incorporating a display panel or display device without departing from the spirit and scope of embodiments according to the present disclosure.

Referring to FIG. 1, the electronic device DD may have a rectangular shape including long sides extending in a first direction DR1 and short sides extending in a second direction DR2 intersecting the first direction DR1 on a plane. However, embodiments according to the present disclosure are not limited thereto, and the electronic device DD may have various shapes such as a circular shape or a polygonal shape rather than a rectangular shape on a plane (e.g., in a plan view, or in a direction perpendicular to a plane of a display surface IS of the electronic device DD).

The electronic device DD may display the image IM in a third direction DR3 through a display surface IS parallel to a surface defined by the first direction DR1 and the second direction DR2. The third direction DR3 may be substantially parallel to a normal direction of the display surface IS. The display surface IS in which the image IM is displayed may correspond to a front surface of the electronic device DD. The image IM may include a still image as well as a dynamic image. FIG. 1 illustrates icon images as an example of the image IM.

FIG. 1 illustrates, by way of example, the electronic device DD having the flat display surface IS. However, embodiments according to the present disclosure are not limited thereto, and the display surface IS of the electronic device DD may further include a curved surface bent from a flat surface.

According to some embodiments, front surfaces (or upper surfaces) and rear surfaces (or lower surfaces) of members constituting the electronic device DD may be defined based on the third direction DR3. The front surface and the rear surface may be opposite to each other in the third direction DR3 and a normal direction of the front surface and the rear surface may be parallel to the third direction DR3. A separation distance between the front surface and the rear surface defined in the third direction DR3 may correspond to a thickness of the member.

In the specification, the wording “on a plane” or “in a plan view” may be defined as a state of being viewed from the third direction DR3. In the specification, the wording “on a cross section” may be defined as a state of being viewed in the first direction DR1 or the second direction DR2. However, the directions indicated by the first direction DR1, the second direction DR2, and the third direction DR3 are relative concepts and may be changed to other directions.

The electronic device DD may be flexible. The wording “flexible” may mean a bendable property and include a completely folded structure to a structure that may be bent by several nanometers. For example, the flexible electronic device DD may include a curved device, a rollable device, a slidable device, or a foldable device. However, the present disclosure is not limited thereto, and the electronic device DD may be rigid.

The display surface IS of the electronic device DD may include a display portion D-DA and a non-display portion D-NDA. The display portion D-DA may be a portion inside a front surface of the electronic device DD in which the image IM is displayed, and the user may visually recognize the image IM through the display portion D-DA. FIG. 1 illustrates, by way of example, the display portion D-DA having a quadrangular shape on a plane, but the shape of the display portion D-DA may be variously changed depending on design of the electronic device DD.

The non-display portion D-NDA may be a part inside the front surface of the electronic device DD, in which the image IM is not displayed. The non-display portion D-NDA may be a portion having a color (e.g., a set or predetermined color) and shielding a light. The non-display portion D-NDA may be adjacent to (e.g., in a periphery or outside a footprint of) the display portion D-DA. For example, the non-display portion D-NDA may be located outside (e.g., in a periphery, surrounding, or outside a footprint of) the display portion D-DA and surround the display portion D-DA. However, this is illustratively illustrated, the non-display portion D-NDA may be adjacent to only one side of the display portion D-DA or located on a side surface rather than the front surface of the electronic device DD, but embodiments according to the present disclosure are not limited thereto, and the non-display portion D-NDA may be omitted.

The electronic device DD may sense an external input applied from the outside. The external input may have various forms such as pressure, temperature, and light provided from the outside. The external input may include an input (e.g., contact by a hand of the user or a pen) in contact with the electronic device DD as well as an input (e.g., hovering) applied in proximity to the electronic device DD.

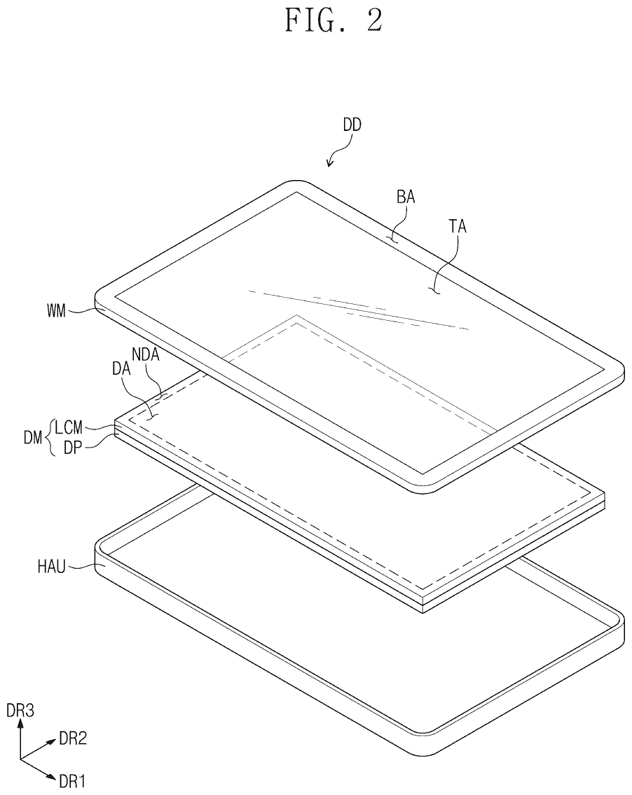

FIG. 2 is an exploded perspective view of an electronic device DD according to some embodiments of the present disclosure.

Referring to FIG. 2, the electronic device DD may include a window WM, a display module DM, and a housing HAU.

The window WM and the housing HAU may be coupled to each other to constitute an exterior of the electronic device DD and provide an internal space in which components of the electronic device DD, such as the display module DM, may be accommodated.

The window WM may be located on the display module DM. The window WM may protect the display module DM from an external impact. A front surface of the window WM may correspond to the display surface IS (see FIG. 1) of the electronic device DD. The front surface of the window WM may include a transmissive area TA and a bezel area BA.

The transmissive area TA of the window WM may be an optically transparent area. The window WM may transmit an image provided by the display module DM through the transmissive area TA, and the user may visually recognize the image. The transmissive area TA may correspond to the display portion D-DA (see FIG. 1) of the electronic device DD.

The window WM may include an optically transparent insulating material. For example, the window WM may include glass, sapphire, or plastic. The window WM may have a single-layer structure or a multi-layer structure. The window WM may further include functional layers, such as a fingerprint preventing layer, a phase control layer, and/or a hard coating layer which are arranged on an optically transparent substrate.

The bezel area BA of the window WM may be provided as an area on which a material having a color (e.g., a set or predetermined color) is deposited, coated, or printed on a transparent substrate. The bezel area BA of the window WM may prevent components of the display module DM arranged to overlap the bezel area BA from being visually recognized from the outside. The bezel area BA may correspond to the non-display portion D-NDA (see FIG. 1) of the electronic device DD.

The display module DM may be located between the window WM and the housing HAU. The display module DM may display an image according to an electric signal. The display module DM may include a display area DA and a non-display area NDA around the display area DA.

The display area DA may be an area that is activated by an electric signal and outputs the image. The display area DA of the display module DM may overlap the transmissive area TA of the window WM. Meanwhile, in the specification, the wording “an area/part and an area/part overlap each other” is not limited to a state in which the area/part and the area/part have the same area and/or the same shape. The image output from the display area DA may be visually recognized from the outside through the transmissive area TA.

The non-display area NDA may be adjacent to the display area DA. For example, the non-display area NDA may surround the display area DA. However, the present disclosure is not limited thereto, and the non-display area NDA may be defined in various shapes. The non-display area NDA may be an area in which a driving circuit for driving elements arranged in the display area DA, signal lines for providing electrical signals to the elements, and pads are arranged. The non-display area NDA of the display module DM may overlap the bezel area BA of the window WM, and components arranged in the non-display area NDA may be prevented from being visually recognized from the outside by the bezel area BA.

The housing HAU may be located under the display module DM and accommodate the display module DM. The housing HAU may protect the display module DM by absorbing an impact applied from the outside to the display module DM and preventing foreign substances/moisture from penetrating into the display module DM. According to some embodiments, the housing HAU may be provided in the form in which a plurality of storage members are coupled.

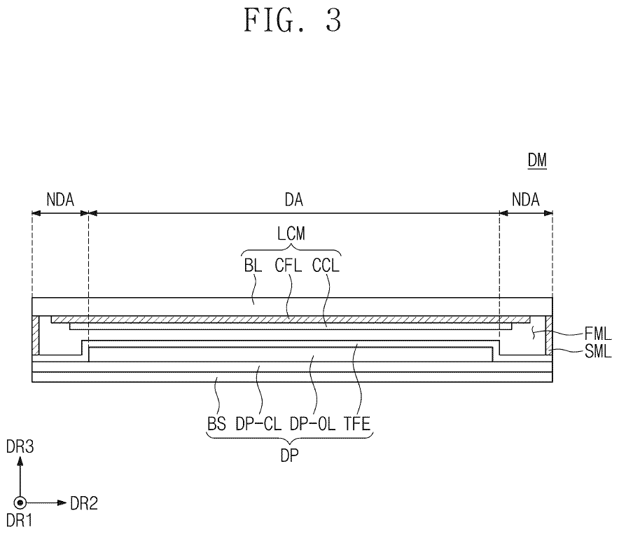

FIG. 3 is a cross-sectional view of the display module DM according to some embodiments of the present disclosure.

Referring to FIGS. 2 and 3, the display module DM may include a display panel DP and a light control member LCM located on the display panel DP.

The display panel DP according to some embodiments may be a light emitting display panel, but embodiments according to the present disclosure are not particularly limited thereto. For example, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum dot light emitting display panel may include a quantum dot and a quantum rod. Hereinafter, the display panel DP will be described as the organic light emitting display panel.

The display panel DP may include a base substrate BS, a circuit layer DP-CL, a display element layer DP-OL, and an encapsulation layer TFE.

The base substrate BS may provide a base surface on which the circuit layer DP-CL is located. The base substrate BS may be a rigid substrate or a flexible substrate. The base substrate BS may include a glass or synthetic resin layer. The synthetic resin layer may include a thermosetting resin. In particular, the synthetic resin layer may be a polyimide-based resin layer, and a material thereof is not particularly limited thereto. The synthetic resin layer may include at least one of an acrylic resin, a methacrylic resin, a polyisoprene, a vinyl resin, an epoxy resin, a urethane resin, a cellulose resin, a siloxane resin, a polyamide resin, or a perylene resin. In addition, the base substrate BS may include a glass substrate, a metal substrate, or an organic/inorganic composite material substrate.

The circuit layer DP-CL may be located on the base substrate BS. The circuit layer DP-CL may include driving elements such as transistors, signal lines, and pads. The circuit layer DP-CL may be located on the base substrate BS. The circuit layer DP-CL may include an insulating layer, a semiconductor pattern, a conductive pattern, a signal line, and the like. The insulating layer, a semiconductor layer, and a conductive layer may be formed on the base substrate BS by a method such as coating or deposition, and the insulating layer, the semiconductor layer, and the conductive layer may be selectively patterned through a plurality of photolithography processes. Accordingly, the semiconductor pattern, the conductive pattern, and the signal line may be formed on the circuit layer DP-CL. The circuit layer DP-CL may include a transistor, a buffer layer, and a plurality of insulating layers.

The display element layer DP-OL may include light emitting elements arranged to overlap the display area DA. The light emitting elements of the display element layer DP-OL may be electrically connected to the driving elements of the circuit layer DP-CL and may output lights through the display area DA according to signals of the driving elements.

The encapsulation layer TFE may be located on the display element layer DP-OL to seal the light emitting elements. The encapsulation layer TFE may include thin films for relatively improving optical efficiency of the light emitting elements or protecting the light emitting elements.

The light control member LCM may be located on the display panel DP. The light control member LCM may be manufactured through a manufacturing process separate from a process of manufacturing the display panel DP and coupled onto the display panel DP. For example, the light control member LCM may be provided on the display panel DP and then coupled to the display panel DP through a bonding process using a sealing member SML.

However, embodiments according to the present disclosure are not limited thereto, and the light control member LCM may be directly located on the display panel DP. In the specification, a state in which components are formed by a continuous process without a separate adhesive layer or a separate adhesive member located therebetween may be expressed as “directly located.” For example, the expression “the light control member LCM is directly located on the display panel DP” may indicate a state in which, after the display panel DP is formed, the light control member LCM is formed on the base surface provided by the display panel DP through a continuous process.

The light control member LCM may convert a wavelength of a light provided by the display panel DP, for example, a source light or may selectively transmit the source light. Further, the light control member LCM may control optical properties of an external light input from the outside of the electronic device DD, thereby reducing external light reflectance.

The light control member LCM may include a base layer BL, a color filter layer CFL, and a light control layer CCL. The base layer BL may be arranged to face the base substrate BS of the display panel DP, and the color filter layer CFL and the light control layer CCL arranged on the base layer BL may be positioned between the display panel DP and the base layer BL.

The light control layer CCL may convert optical properties of the source light provided from the display panel DP. For example, the light control layer CCL may include a quantum dot that changes a wavelength of the source light provided by the display panel DP. The source light passing through the quantum dot included in the light control layer CCL may be output as a color light having a color different from that of the source light. The light control layer CCL may further include a transmissive part that transmits the source light provided by the display panel DP.

The color filter layer CFL may include color filters having colors (e.g., set or predetermined colors). The color filters may transmit or absorb lights passing through the light control layer CCL according to the colors of the color filters. The color filter layer CFL may absorb a light that is not converted by the light control layer CCL to prevent or reduced degradation of color purity or color reproducibility of the electronic device DD.

The color filters of the color filter layer CFL may absorb an external light input from the outside of the electronic device DD depending on the colors of the color filters. The color filters may filter the external light to the same color as a color of a light output by pixels, thereby reducing external light reflectance.

The sealing member SML may be located in the non-display area NDA that is an outer portion of the display module DM and prevent or reduce contaminants or foreign substances such as oxygen, or moisture being introduced into the display module DM from the outside. The sealing member SML may be formed from a sealant including a curable resin.

The display module DM may further include a filler layer FML located between the display panel DP and the light control member LCM. The filler layer FML may fill a space between the display panel DP and the light control member LCM. The filler layer FML may function as a buffer between the display panel DP and the light control member LCM. The filler layer FML may absorb an impact and increase strength of the display module DM.

The filler layer FML may include a polymer resin. For example, the filler layer FML may include an acrylic-based resin or an epoxy-based resin. However, according to some embodiments, as the light control member LCM is directly located on the display panel DP, the filler layer FML and the sealing member SML may be omitted. Further, according to some embodiments in which the light control member LCM is directly located on the display panel DP, the display panel DP provides the base surface, and thus the base layer BL of the light control member LCM may be omitted.

Meanwhile, the electronic device DD may further include an input sensing module. The input sensing module may acquire coordinate information of the external input applied from the outside of the electronic device DD. The input sensing module may be driven in various methods such as a capacitive method, a resistive method, an infrared method, or a pressure method, and the present disclosure is not limited to one method.

According to some embodiments, the input sensing module may be located on the display module DM. The input sensing module may be directly located on the display module DM through a continuous process, but the present disclosure is not limited thereto, and the input sensing module may be attached to the display module DM through a separate adhesive layer. Alternatively, the input sensing module may be located between the components of the display module DM. For example, the input sensing module may be located between the display panel DP and the light control member LCM.

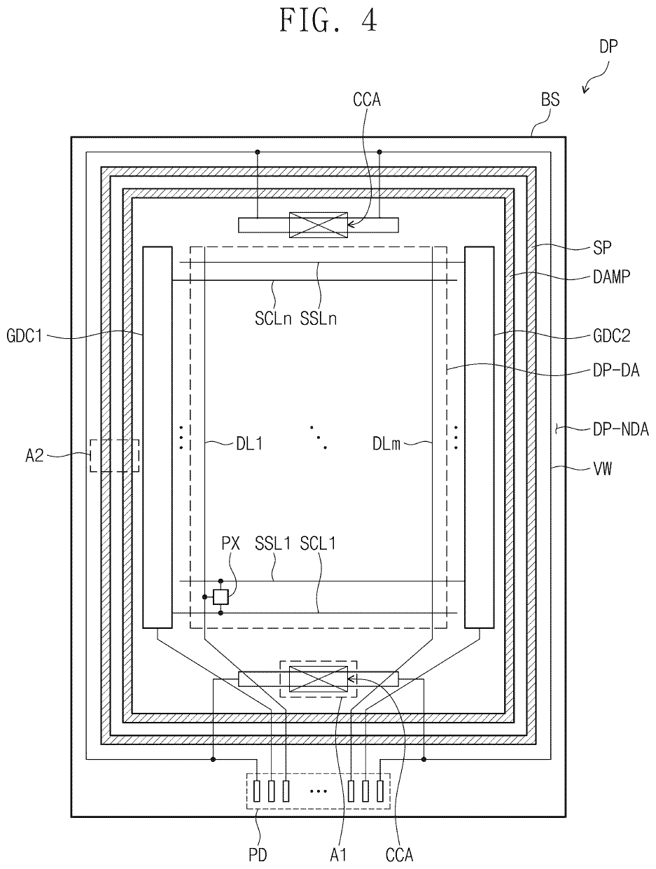

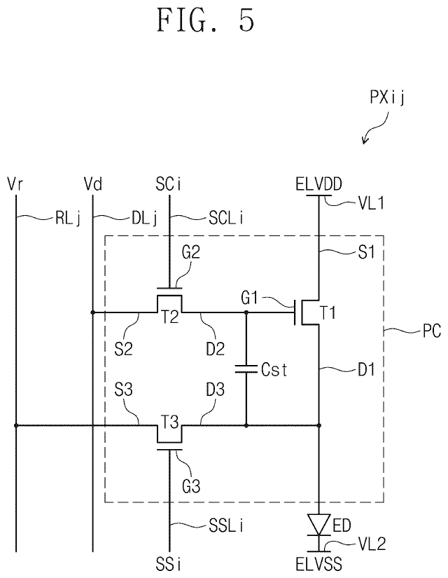

FIG. 4 is a plan view of the display panel DP according to some embodiments of the present disclosure. FIG. 5 is an equivalent circuit diagram of a pixel PXij according to some embodiments of the present disclosure.

Referring to FIG. 4, the display panel DP may include the base substrate BS in which a display area DP-DA and a non-display area DP-NDA are defined. The display area DP-DA and the non-display area DP-NDA may correspond to the display area DA and the non-display area NDA of the display module DM illustrated in FIG. 3, respectively. The display panel DP may include pixels PX arranged in the display area DP-DA and signal lines SCL1 to SCLn, SSL1 to SSLn, and DL1 to DLm electrically connected to the pixels PX. The display panel DP may include a first gate driving circuit GDC1, a second gate driving circuit GDC2, and a pad part PD arranged in the non-display area DP-NDA.

Each of the pixels PX may include a light emitting element and a pixel driving circuit including transistors (e.g., a switching transistor, a driving transistor, and the like) connected to the light emitting element and a capacitor connected to the transistors. The pixels PX may emit lights in accordance with electrical signals applied to the pixels PX. Although FIG. 4 illustrates, by way of example, the pixels PX arranged in a matrix form, the arrangement of the pixels PX is not limited thereto.

The signal lines SCL1 to SCLn, SSL1 to SSLn, and DL1 to DLm may include driving scan lines SCL1 to SCLn, sensing scan lines SSL1 to SSLn, and data lines DL1 to DLm, wherein n and m each are positive integer. Each of the pixels PX may be connected to a corresponding driving scan line among the driving scan lines SCL1 to SCLn, a corresponding sensing scan line among the sensing scan lines SSL1 to SSLn, and a corresponding data line among the data lines DL1 to DLm. However, embodiments according to the present disclosure is not limited thereto, and more types or more numbers of signal lines may be provided on the display panel DP depending on the circuit configuration of the pixels PX.

The first gate driving circuit GDC1 may generate driving scan signals and sequentially output the driving scan signals to the driving scan lines SCL1 to SCLn. The second gate driving circuit GDC2 may generate sensing scan signals and sequentially output the sensing scan signals to the sensing scan lines SSL1 to SSLn. According to some embodiments of the present disclosure, the first gate driving circuit GDC1 may be adjacent to a first side of the display area DP-DA, and the second gate driving circuit GDC2 may be adjacent to a second side of the display area DP-DA. However, embodiments according to the present disclosure are not limited thereto. For example, the first gate driving circuit GDC1 and the second gate driving circuit GDC2 may be arranged on one side (i.e., the first side or the second side) of the display area DP-DA.

Each of the first gate driving circuit GDC1 and the second gate driving circuit GDC2 may further output another control signal to the pixel driving circuit of each of the pixels PX. According to some embodiments, the first gate driving circuit GDC1, the second gate driving circuit GDC2, and the pixels PX may include transistors formed through a low temperature polycrystalline silicon (LTPS) process, a low temperature polycrystalline oxide (LTPO) process, or an oxide semiconductor process.

The display panel DP may further include a dam part DAMP and a support part SP arranged in the non-display area DP-NDA. The dam part DAMP is located in the form of a closed loop along an edge of the display area DP-DA in the non-display area DP-NDA. According to some embodiments of the present disclosure, the dam part DAMP may include one or more sub-dam portions.

The support part SP is located in the non-display area DP-NDA to surround the dam part DAMP. According to some embodiments of the present disclosure, the support part SP may be located outside the dam part DAMP. According to some embodiments of the present disclosure, the support part SP may have a closed loop shape, but embodiments of the present disclosure are not limited thereto.

The display panel DP may further include a voltage wiring VW located outside the support part SP in the non-display area DP-NDA. The voltage wiring VW may be a wiring that receives a second driving voltage ELVSS illustrated in FIG. 5. The voltage wiring VW may be electrically connected to a second electrode (i.e., a cathode) of a light emitting element ED illustrated in FIG. 5 and a second voltage line VL2 illustrated in FIG. 5. According to some embodiments of the present disclosure, a contact area CCA (referred to as a cathode contact area) in which the voltage wiring VW and the second electrode of the light emitting element ED are in contact with each other may be provided in the display panel DP. The contact area CCA may be positioned between the dam part DAMP and the display area DP-DA. FIG. 4 illustrates two contact areas CCA, but embodiments of the present disclosure are not limited thereto. That is, the number and the positions of the contact areas CCA may be variously modified.

The pad part PD of the display panel DP may include a plurality of pads arranged in one direction in the non-display area DP-NDA. The pad part PD may be a part connected to a circuit board. The pad part PD may be located outside the support part SP. The pad part PD may include data pads connected to the data lines DL1 to DLm, control signal pads connected to the first gate driving circuit GDC1 and the second gate driving circuit GDC2, and voltage pads connected to the voltage wiring VW.

FIG. 5 illustrates, by way of example, a circuit diagram of the one pixel PXij among the pixels PX. FIG. 5 illustrates, by way of example, the pixel PXij connected to an i^{th} driving scan line SCLi, an i^{th} sensing scan line SSLi, a j^{th} data line DLj, and a j^{th} reference line RLj, wherein i is a positive integer less than or equal to n and j is a positive integer less than or equal to m.

Referring to FIG. 5, the pixel PXij may include a pixel driving circuit PC and the light emitting element ED. The pixel driving circuit PC may include transistors T1, T2, and T3 and a capacitor Cst.

The transistors T1, T2, and T3 may be formed through the LTPS process, the LTPO process, or the oxide semiconductor process. Each of the transistors T1, T2, and T3 may include one of a silicon semiconductor and an oxide semiconductor. The oxide semiconductor may include a crystalline or amorphous oxide semiconductor, and the silicon semiconductor may include amorphous silicon or polycrystalline silicon, but embodiments according to the present disclosure are not limited thereto.

Each of the transistors T1, T2, and T3 may be an N-type transistor or a P-type transistor. Hereinafter, each of the transistors T1, T2, and T3 may be described as the N-type transistor, but embodiments according to the present disclosure are not limited thereto, and each of the transistors T1, T2, and T3 may be the P-type transistor or the N-type transistor depending on an applied signal. In this case, a source and a drain of the P-type transistor may correspond to a drain and a source of the N-type transistor.

The transistors T1, T2, and T3 of the pixel driving circuit PC may include a first transistor T1, a second transistor T2, and a third transistor T3. However, the pixel driving circuit PC may further include an additional transistor and an additional capacitor, and the present disclosure is not limited to an embodiment.

Each of the first transistor T1, the second transistor T2, and the third transistor T3 may include a first electrode, a second electrode, and a third electrode. The first electrode of each of the first transistor T1, the second transistor T2, and the third transistor T3 is referred to as a source or a source electrode, the second electrode of each of the first transistor T1, the second transistor T2, and the third transistor T3 is referred to as a drain or a drain electrode, and the third electrode of each of the first transistor T1, the second transistor T2, and the third transistor T3 is referred to as a gate or a gate electrode.

The first transistor T1 may be electrically connected between the light emitting element ED and a first voltage line VL1 that receives a first driving voltage ELVDD. The first transistor T1 may include a first source S1 that receives the first driving voltage ELVDD, a first drain D1 connected to a first electrode of the light emitting element ED, and a first gate G1 connected to the capacitor Cst. The first transistor T1 may control a driving current flowing through the light emitting element ED from the first voltage line VL1 in response to a voltage value stored in the capacitor Cst. The first transistor T1 may be defined as a driving transistor.

The second transistor T2 may be electrically connected between the j^{th} data line DLj and the capacitor Cst. The second transistor T2 may include a second source S2 connected to the j^{th} data line DLj, a second drain D2 connected to the capacitor Cst, and a second gate G2 connected to the i^{th} driving scan line SCLi that receives an i^{th} driving scan signal SCi. The second transistor T2 may provide a data voltage Vd to the first transistor T1 in response to the i^{th} driving scan signal SCi. The second transistor T2 may be defined as a switching transistor.

The third transistor T3 may be electrically connected between the j^{th} reference line RLj and the light emitting element ED. The third transistor T3 may include a third source S3 connected to the j^{th} reference line RLj, a third drain D3 connected to the first electrode of the light emitting element ED, and a third gate G3 connected to the i^{th} sensing scan line SSLi that receives an i^{th} sensing scan signal SSi. The j^{th} reference line RLj may receive a reference voltage Vr.

The capacitor Cst may store various voltage difference values according to an input signal. For example, the capacitor Cst may store a voltage corresponding to a difference between a voltage received from the second transistor T2 and the first driving voltage ELVDD.

The light emitting element ED may include a first electrode and a second electrode. According to some embodiments, the first electrode of the light emitting element ED may be an anode, and the second electrode thereof may be a cathode. The first electrode of the light emitting element ED may be connected to the first drain D1 of the first transistor T1, and the second electrode of the light emitting element ED may be connected to the second voltage line VL2 that receives the second driving voltage ELVSS. The light emitting element ED may emit a light corresponding to a magnitude of the driving current provided through the first transistor T1.

Meanwhile, the equivalent circuit of the pixel PXij in the present disclosure is not limited to the equivalent circuit illustrated in FIG. 5. According to some embodiments of the present disclosure, the pixel PXij may be implemented in various forms to allow the light emitting element ED to emit a light.

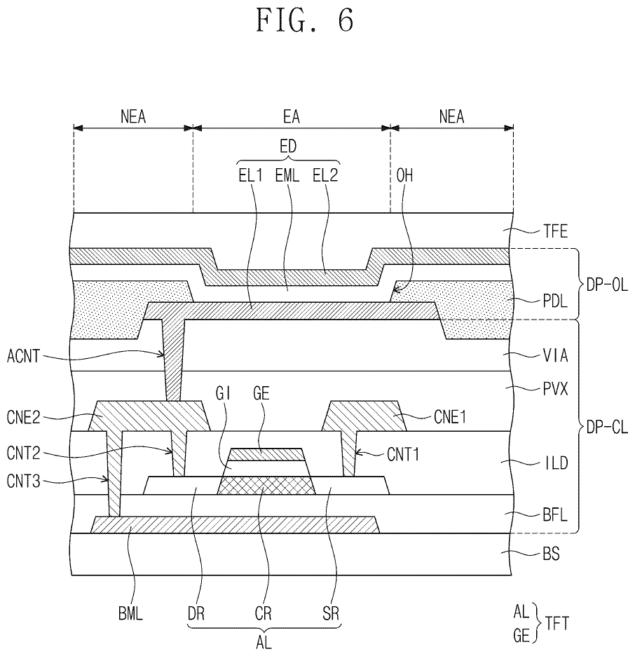

FIG. 6 is a cross-sectional view of a portion of the display panel DP according to some embodiments of the present disclosure.

FIG. 6 illustrates a cross section corresponding to the display area DP-DA of FIG. 4, this is illustrative, and the present disclosure is not limited thereto.

Referring to FIG. 6, the display panel DP may include the base substrate BS, the circuit layer DP-CL, the display element layer DP-OL, and the encapsulation layer TFE.

The circuit layer DP-CL may include a conductive pattern BML, a buffer layer BFL, a transistor TFT, a gate insulating layer GI, an interlayer insulating layer ILD, a protective layer PVX, and a via insulating layer VIA.

The conductive pattern BML may be located on the base substrate BS. The conductive pattern BML may include one of molybdenum (Mo), aluminum (Al), chromium (Cr), gold (Au), titanium (Ti), nickel (Ni), neodymium (Nd), and copper (Cu), or an alloy thereof. FIG. 6 illustrates the conductive pattern BML as one layer, but the present disclosure is not limited thereto. For example, the conductive pattern BML may have a single-layer structure including one pattern layer or may include more pattern layers.

The buffer layer BFL may be located on the base substrate BS to cover the conductive pattern BML. The buffer layer BFL may relatively improve a coupling force between the base substrate BS and the semiconductor pattern AL. The buffer layer BFL may include at least one inorganic film. For example, the buffer layer BFL may include a silicon oxide layer and a silicon nitride layer. The silicon oxide layer and the silicon nitride layer may be alternately laminated.

The transistor TFT may be located on the buffer layer BFL. The transistor TFT may include a semiconductor pattern AL and a gate electrode GE. The transistor TFT may correspond to the first transistor T1 illustrated in FIG. 5.

The semiconductor pattern AL may be located on the buffer layer BFL. The semiconductor pattern AL may overlap the conductive pattern BML on a plane. The semiconductor pattern AL may include polysilicon. However, the present disclosure is not limited thereto, and the semiconductor pattern AL may include amorphous silicon or a metal oxide. FIG. 6 illustrates, by way of example, the semiconductor pattern AL for the one transistor TFT, but a plurality of semiconductor patterns may be arranged on the buffer layer BFL. The plurality of semiconductor patterns may be arranged in a specific rule. The semiconductor pattern AL may have different electrical properties depending on whether the semiconductor pattern AL is doped.

The semiconductor pattern AL may include a source area SR, a drain area DR, and a channel area CR. The source area SR and the drain area DR may extend in opposite directions with the channel area CR interposed therebetween. That is, the drain area DR may be spaced apart from the source area SR, and the channel area CR may be formed between the source area SR and the drain area DR.

The semiconductor pattern AL may include a first area having high conductivity and a second area having low conductivity. The first area may be doped with an N-type dopant or a P-type dopant. A P-type transistor may include a doped area doped with the P-type dopant, and an N-type transistor may include a doped area doped with the N-type dopant. The second area may be a non-doped area or may be an area doped at a concentration that is lower than a concentration of the first area.

The conductivity of the first area is greater than the conductivity of the second area. The first area may serve as an electrode or a signal line of the transistor TFT. The second area may correspond to the channel area CR of the transistor TFT. In other words, a portion of the semiconductor pattern AL may be the channel area CR of the transistor TFT, another portion thereof may be the source area SR or the drain area DR of the transistor TFT, and still another portion thereof may be a connection electrode or a connection signal line.

The source area SR of the transistor TFT may correspond to the first source S1 of the first transistor T1 illustrated in FIG. 5, and the drain area DR of the transistor TFT may correspond to the first drain D1 of the first transistor T1 illustrated in FIG. 5.

The gate insulating layer GI may be located on the semiconductor pattern AL. The gate insulating layer GI may overlap the channel area CR of the semiconductor pattern AL and may cover a portion of the semiconductor pattern AL.

The gate electrode GE may be located on the gate insulating layer GI. The gate electrode GE overlaps the gate insulating layer GI. The gate insulating layer GI is located between the gate electrode GE and the channel area CR of the semiconductor pattern AL. The gate electrode GE may correspond to the first gate G1 of the first transistor T1 illustrated in FIG. 5.

The interlayer insulating layer ILD may be located on the base substrate BS to cover the semiconductor pattern AL and the gate electrode GE. A first contact hole CNT1 and a second contact hole CNT2, through which portions of the source area SR and the drain area DR of the semiconductor pattern AL are exposed, may be defined in the interlayer insulating layer ILD.

A first connection electrode CNE1 and a second connection electrode CNE2 may be formed on the interlayer insulating layer ILD and connected to the source area SR and the drain area DR through the first contact hole CNT1 and the second contact hole CNT2, respectively. According to some embodiments of the present disclosure, the second connection electrode CNE2 may be electrically connected to the conductive pattern BML. A third contact hole CNT3, through which a portion of the conductive pattern BML is exposed, may be formed in the buffer layer BFL and the interlayer insulating layer ILD, and the second connection electrode CNE2 may be connected to the conductive pattern BML through the third contact hole CNT3. However, the present disclosure is not limited thereto. The conductive pattern BML may be electrically connected to the first voltage line VL1 illustrated in FIG. 5.

Each of the first connection electrode CNE1 and the second connection electrode CNE2 may have a structure in which a plurality of layers are laminated. Each of the first connection electrode CNE1 and the second connection electrode CNE2 may include a first sub-layer and a second sub-layer that are sequentially laminated. However, embodiments according to the present disclosure are not limited thereto, and each of the first connection electrode CNE1 and the second connection electrode CNE2 may have a structure in which three or more layers are laminated.

Each of the first connection electrode CNE1 and the second connection electrode CNE2 may be formed of any one of molybdenum (Mo), aluminum (Al), chromium (Cr), gold (Au), titanium (Ti), nickel (Ni), neodymium (Nd), copper (Cu), and an indium tin oxide (ITO), or an alloy thereof. For example, the first sub-layer may include copper (Cu), and the second sub-layer may include titanium (Ti) or ITO. However, embodiments according to the present disclosure are not limited thereto.

The protective layer PVX may be located on the interlayer insulating layer ILD to cover the first connection electrode CNE1 and the second connection electrode CNE2. The interlayer insulating layer ILD and the protective layer PVX may be inorganic layers. The via insulating layer VIA may be located on the protective layer PVX to cover the protective layer PVX. The via insulating layer VIA may be an organic layer. A first electrode EL1 may be connected to the second connection electrode CNE2 by an anode contact hole ACNT (or referred to as an anode contact portion) defined through the protective layer PVX and the via insulating layer VIA.

The display element layer DP-OL may include the light emitting element ED and a pixel defining layer PDL.

The light emitting element ED may include the first electrode EL1 (referred to as an anode), a second electrode EL2 (referred to as a cathode or a second electrode layer EL2) facing the first electrode EL1, and a light emitting layer EML located between the first electrode EL1 and the second electrode EL2. The light emitting layer EML included in the light emitting element ED may include an organic light emitting material or a quantum dot as a light emitting material. The light emitting element ED may further include a hole transport layer and/or an electron transport layer.

The pixel defining layer PDL may be located on the circuit layer DP-CL and may cover a portion of the first electrode EL1. A pixel opening OH may be defined in the pixel defining layer PDL. At least a portion of the first electrode EL1 is exposed through the pixel opening OH of the pixel defining layer PDL. A light emitting area EA may be defined to correspond to the portion of the first electrode EL1 exposed by the pixel opening OH of the pixel defining layer PDL. A periphery of the light emitting area EA may be defined as a non-light emitting area NEA.

The first electrode EL1 may be located on the circuit layer DP-CL. The first electrode EL1 may include a transmissive conductive material, a semi-transmissive conductive material, or a reflective conductive material.

The light emitting layer EML may be located on the first electrode EL1. The light emitting layer EML may be commonly located in the light emitting area EA and the non-light emitting area NEA. However, embodiments according to the present disclosure are not limited thereto, and according to some embodiments, the light emitting layer EML may be located in the pixel opening OH. That is, the light emitting layer EML may be arranged in an island shape or arrangement to correspond to the light emitting area EA distinguished by the pixel defining layer PDL.

When the light emitting layer EML is arranged or formed in common, a source light may be generated. According to some embodiments, the light emitting layer EML may emit a blue light. That is, the blue light may be the source light. Meanwhile, when the light emitting layers EML are arranged in an island shape to correspond to the light emitting areas EA, each of the light emitting layers EML may emit one of a blue light, a green light, and a red light.

The light emitting layer EML may have a multi-layer structure having a single layer made of a single material, a single layer made of a plurality of different materials, or a plurality of layers made of a plurality of different materials. The light emitting layer EML may include a fluorescent or phosphorescent material. In the light emitting element ED according to some embodiments, the light emitting layer EML may include a light emitting material such as an organic light emitting material, a metal organic complex, or a quantum dot.

The light emitting layer EML may have a multi-layer structure unlike the illustration of FIG. 6. For example, the light emitting layer EML may include a first light emitting layer, a charge generating layer, and a second light emitting layer that emits a light having a different color from that of the first light emitting layer, which are sequentially laminated in the third direction DR3 (refer to FIG. 3). The first light emitting layer may emit, for example, a blue light, and the second light emitting layer may emit, for example, a green light. The charge generating layer may be located between the first light emitting layer and the second light emitting layer, supply an electron or a hole to each of the first light emitting layer and the second light emitting layer, and thus relatively improve light emitting efficiency.

The second electrode EL2 may be located on the light emitting layer EML. The second electrode EL2 may be a common electrode. The second electrode EL2 may include a transmissive conductive material.

The encapsulation layer TFE may be located on the second electrode EL2. The encapsulation layer TFE may protect the display element layer DP-OL from moisture and oxygen and prevent or reduce inflow of contaminants or foreign substances such as dust.

The encapsulation layer TFE may include at least one inorganic film. The inorganic film may include at least one of a silicon nitride, a silicon oxy nitride, a silicon oxide, a titanium oxide, or an aluminum oxide. The encapsulation layer TFE may include at least one organic film. The organic film may include an organic polymer material formed from an acrylate-based resin. However, this is illustrative, and embodiments according to the present disclosure are not limited thereto.

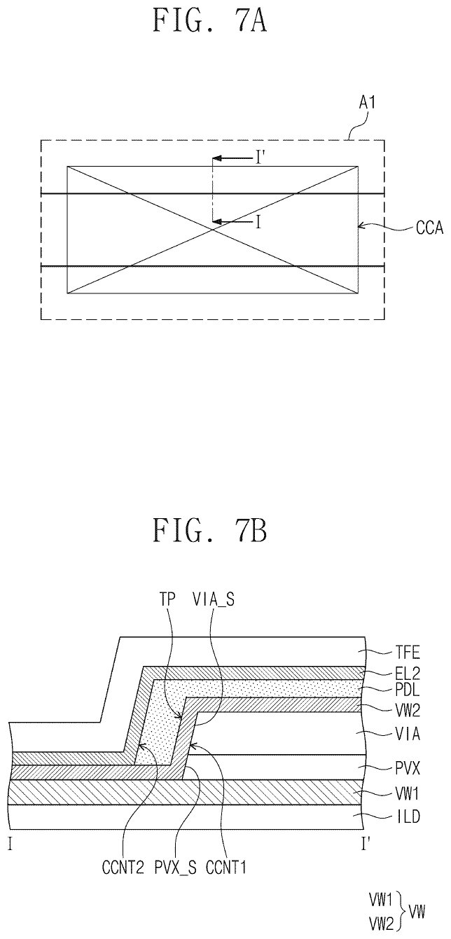

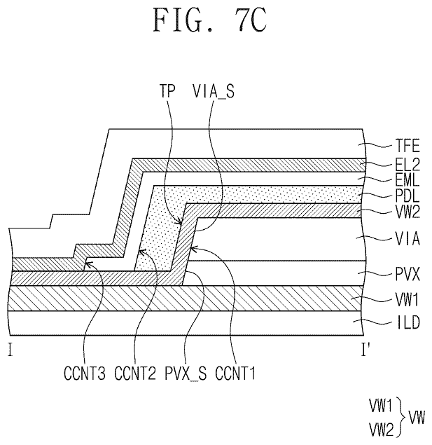

FIG. 7A is an enlarged plan view of the area A1 illustrated in FIG. 4. FIG. 7B is a cross-sectional view along the cut line I-I′ illustrated in FIG. 7A according to some embodiments of the present disclosure. FIG. 7C is a cross-sectional view along the cut line I-I′ illustrated in FIG. 7A according to some embodiments of the present disclosure.

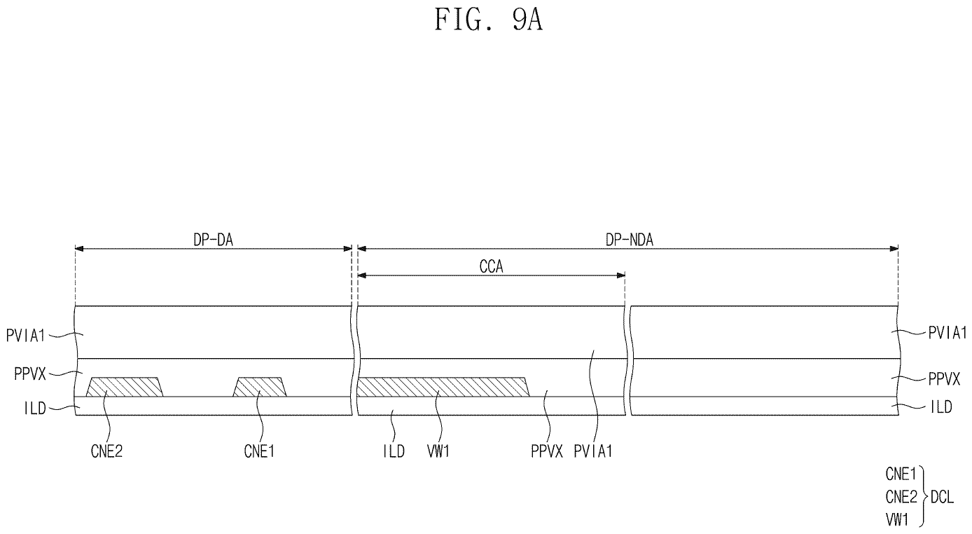

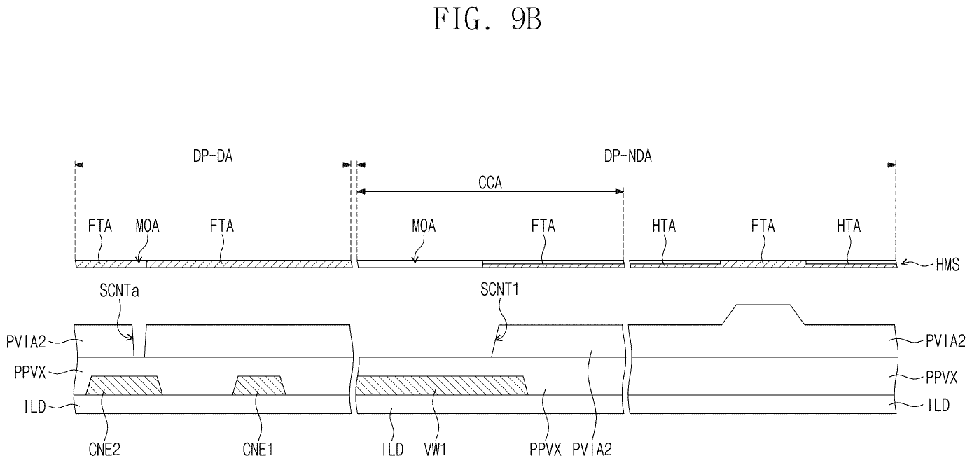

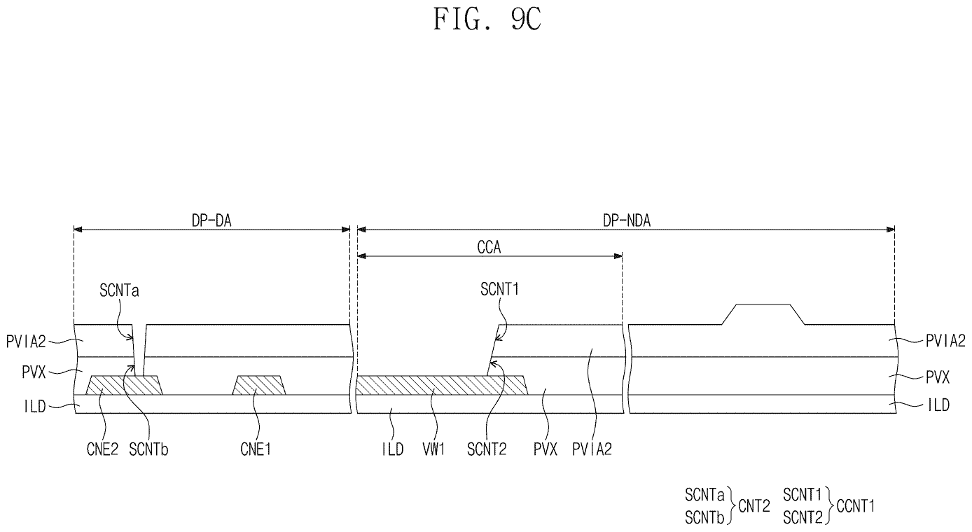

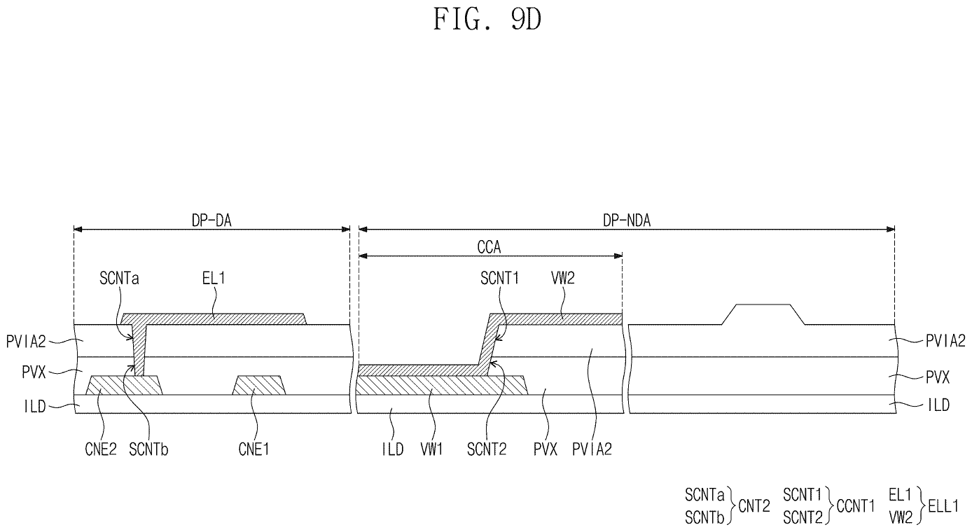

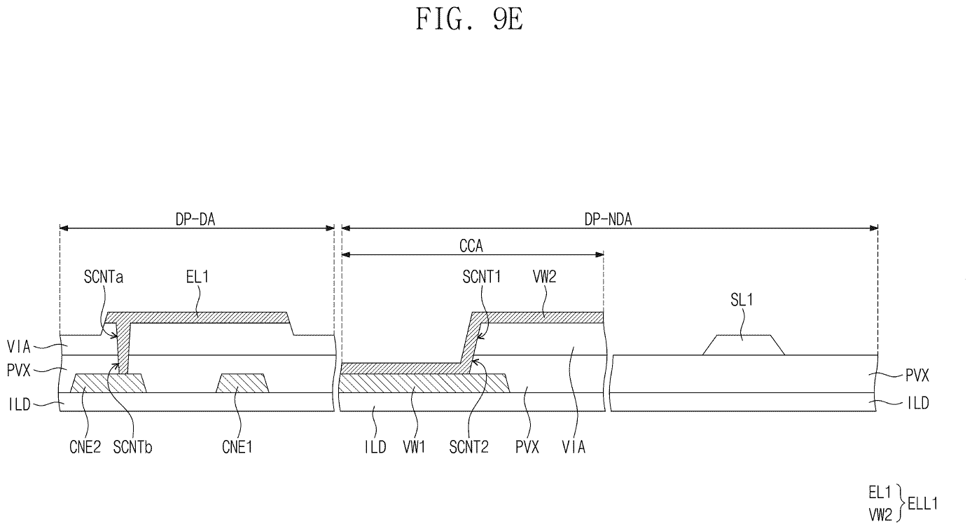

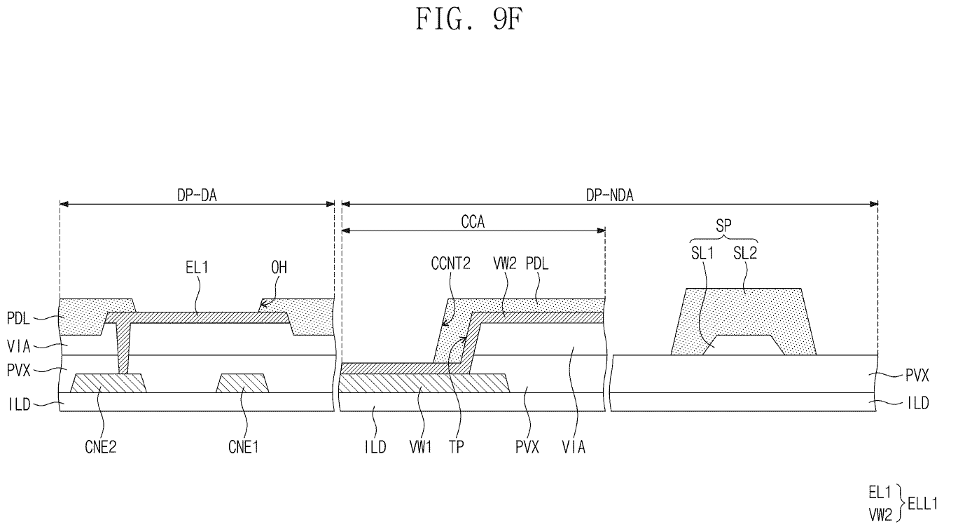

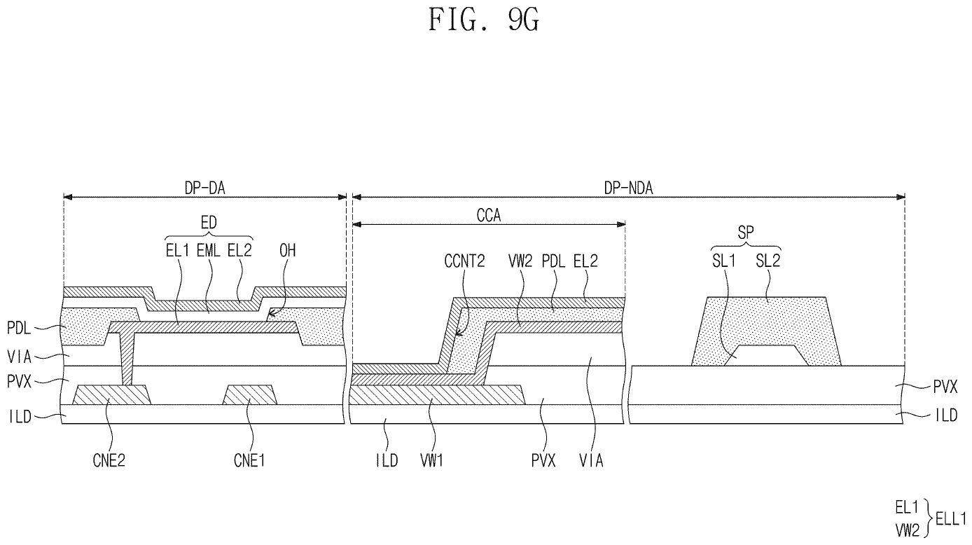

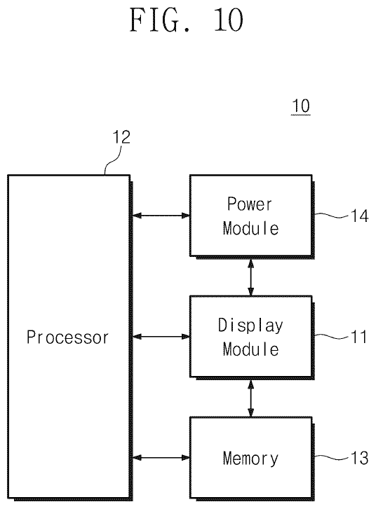

Referring to FIGS. 7A and 7B, the display panel DP may include the voltage wiring VW located in the non-display area DP-NDA (refer to FIG. 4). According to some embodiments of the present disclosure, the voltage wiring VW may include a first voltage wiring VW1 and a second voltage wiring VW2. The first voltage wiring VW1 is included in a data conductive layer DCL illustrated in FIG. 9A, and the second voltage wiring VW2 is included in a first electrode layer ELL1 illustrated in FIG. 9F. That is, the first voltage wiring VW1 is located on the interlayer insulating layer ILD, and the second voltage wiring VW2 is located on the via insulating layer VIA.

The first voltage wiring VW1 and the second voltage wiring VW2 may be connected to each other in the contact area CCA. That is, the first voltage wiring VW1 and the second voltage wiring VW2 may be connected to each other through a first contact portion CCNT1 provided through the protective layer PVX and the via insulating layer VIA in the contact area CCA. A portion of the first voltage wiring VW1 may be exposed through the first contact portion CCNT1, and the second voltage wiring VW2 may be connected to the portion of the first voltage wiring VW1 exposed through the first contact portion CCNT1.

A first side surface PVX_S defining the first contact portion CCNT1 is provided in the protective layer PVX, and a second side surface VIA_S defining the first contact portion CCNT1 is provided in the via insulating layer VIA. The first side surface PVX_S and the second side surface VIA_S may be directly connected to each other to form a continuous inclined surface (i.e., one inclined surface). The second voltage wiring VW2 covers the first side surface PVX_S and the second side surface VIA_S.

The pixel defining layer PDL is located on the second voltage wiring VW2. A second contact portion CCNT2, through which a portion of the second voltage wiring VW2 is exposed, is provided in the pixel defining layer PDL. A width (or a size) of the second contact portion CCNT2 may be smaller than a width (or a size) of the first contact portion CCNT1. Thus, the pixel defining layer PDL may cover a tapered portion TP of the second voltage wiring VW2 covering the first side surface PVX_S of the protective layer PVX and the second side surface VIA_S of the via insulating layer VIA.

The second electrode EL2 is formed on the pixel defining layer PDL. The second electrode EL2 may be connected to a portion of the second voltage wiring VW2 exposed through the second contact portion CCNT2. The encapsulation layer TFE is provided on the second electrode EL2. Thus, the tapered portion TP of the second voltage wiring VW2 is double covered by the pixel defining layer PDL, and thus a phenomenon in which moisture penetrates through the tapered portion TP and a phenomenon in which a profile of the tapered portion TP is collapsed due to a subsequent process may be prevented or reduced.

As illustrated in FIG. 7C, in the contact area CCA (refer to FIG. 7A), the light emitting layer EML may be further located between the pixel defining layer PDL and the second electrode EL2. A third contact portion CCNT3, through which the second voltage wiring VW2 is exposed in the contact area CCA, may be provided in the light emitting layer EML. The second electrode EL2 may be connected to the portion of the second voltage wiring VW2, which is exposed through the second contact portion CCNT2 and the third contact portion CCNT3. In an embodiment, the second electrode layer EL2 may be connected to the second voltage wiring VW2 by the second contact portion CCNT2. A width (or a size) of the third contact portion CCNT3 may be smaller than a width (or a size) of the second contact portion CCNT2.

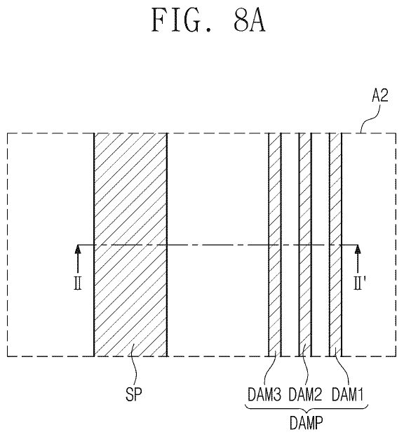

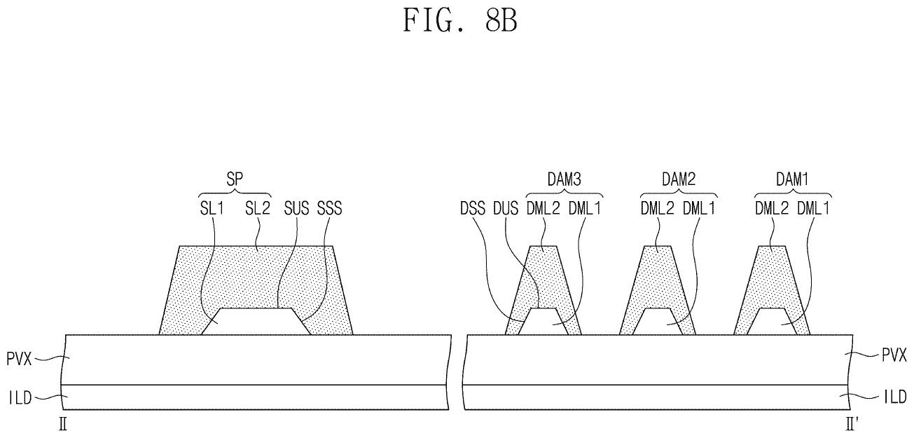

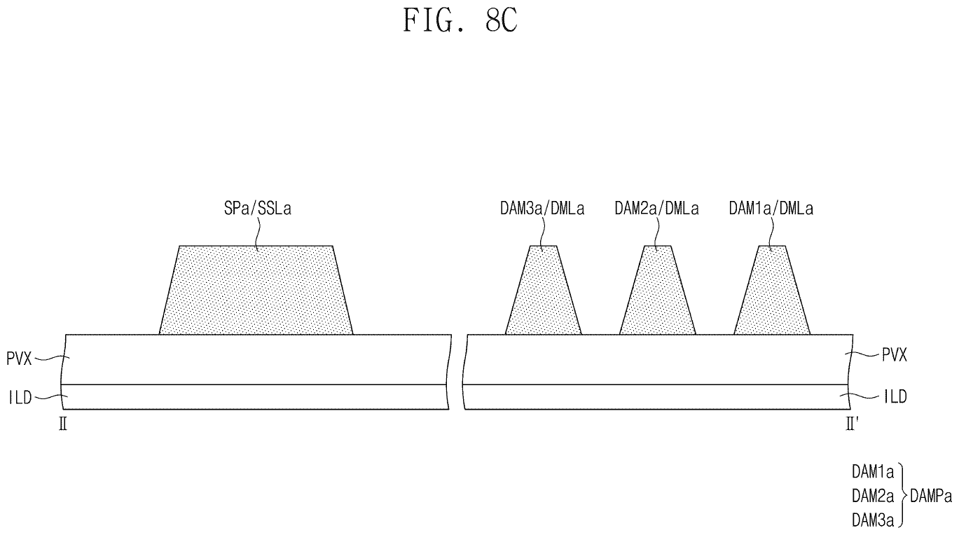

FIG. 8A is an enlarged plan view of the area A2 illustrated in FIG. 4. FIG. 8B is a cross-sectional view along the cut line II-II′ illustrated in FIG. 8A according to some embodiments of the present disclosure. FIG. 8C is a cross-sectional view along the cut line II-II′ illustrated in FIG. 8A according to some embodiments of the present disclosure.

Referring to FIGS. 4, 8A, and 8B, the dam part DAMP may include one or more sub-dam portions. According to some embodiments of the present disclosure, the dam part DAMP may include three sub-dam portions DAM1, DAM2, and DAM3, but embodiments of the present disclosure are not limited thereto. The three sub-dam portions DAM1, DAM2, and DAM3 may be referred to as a first sub-dam portion DAM1, a second sub-dam portion DAM2, and a third sub-dam portion DAM3, respectively. The first sub-dam portion DAM1, the second sub-dam portion DAM2, and the third sub-dam portion DAM3 may be arranged in parallel with each other and may be sequentially arranged in a direction away from the display area DP-DA. Thus, the third sub-dam portion DAM3 may be located outside the first sub-dam portion DAM1 and the second sub-dam portion DAM2.

Each of the first sub-dam portion DAM1, the second sub-dam portion DAM2, and the third sub-dam portion DAM3 may have a quadrangular closed loop shape and may have the same width. However, embodiments of the present disclosure are not limited thereto. Shapes of the first sub-dam portion DAM1, the second sub-dam portion DAM2, and the third sub-dam portion DAM3 may be changed according to a shape of the display area DP-DA or the display panel DP, and widths of the first sub-dam portion DAM1, the second sub-dam portion DAM2, and the third sub-dam portion DAM3 may be different from each other.

As illustrated in FIG. 8B, each of the first sub-dam portion DAM1, the second sub-dam portion DAM2, and the third sub-dam portion DAM3 may include a first dam layer DML1 and a second dam layer DML2. The first dam layer DML1 is located on the protective layer PVX, and the second dam layer DML2 is located on the protective layer PVX to cover the first dam layer DML1. According to some embodiments of the present disclosure, the second dam layer DML2 may cover (completely cover) an upper surface DUS and a side surface DSS of the first dam layer DML1. A width of the second dam layer DML2 may be greater than a width of the first dam layer DML1.

According to some embodiments of the present disclosure, the second dam layer DML2 may be formed of the same material as the pixel defining layer PDL. The second dam layer DML2 may have lower moisture permeability than that of the first dam layer DML1. Thus, the first dam layer DML1 having relatively high moisture permeability is completely covered by the second dam layer DML2 having relatively low moisture permeability, and thus moisture permeation preventing or reducing performance of each of the first sub-dam portion DAM1, the second sub-dam portion DAM2, and the third sub-dam portion DAM3 may be prevented from being degraded.

The support part SP may be located adjacent to the third sub-dam portion DAM3 and may be located outside the third sub-dam portion DAM3. A width of the support part SP may be greater than width of each of the first sub-dam portion DAM1, the second sub-dam portion DAM2, and the third sub-dam portion DAM3.

The support part SP may include a first support layer SL1 and a second support layer SL2. The first support layer SL1 is located on the protective layer PVX, and the second support layer SL2 is located on the protective layer PVX to cover the first support layer SL1. According to some embodiments of the present disclosure, the second support layer SL2 may cover (completely cover) an upper surface SUS and a side surface SSS of the first support layer SL1. A width of the second support layer SL2 may be greater than a width of the first support layer SL1.

According to some embodiments of the present disclosure, the second support layer SL2 may be formed of the same material as the pixel defining layer PDL. The second support layer SL2 may have lower moisture permeability than that of the first support layer SL1. Thus, the first support layer SL1 having relatively high moisture permeability is completely covered by the second support layer SL2 having relatively low moisture permeability, and thus moisture permeation preventing performance of the support part SP may be prevented from being degraded.

Referring to FIG. 8C, a dam part DAMPa includes a first sub-dam portion DAM1a, a second sub-dam portion DAM2a, and a third sub-dam portion DAM3a. Each of the first sub-dam portion DAM1a, the second sub-dam portion DAM2a, and the third sub-dam portion DAM3a may include a single dam layer DMLa. The dam layer DMLa is located on the protective layer PVX. According to some embodiments of the present disclosure, the dam layer DMLa and the pixel defining layer PDL may be located on the same layer.

A support part SPa may include one support layer SSLa. The support layer SSLa is located on the protective layer PVX. The support layer SSLa may be located on the same layer as the pixel defining layer PDL.

According to some embodiments of the present disclosure, the dam part DAMPa and the support part SPa include only the dam layer DMLa and the support layer SSLa, respectively. The dam layer DMLa and the support layer SSLa are made of the same material as the pixel defining layer PDL having relatively high moisture permeability, and thus moisture permeation preventing performance of the dam part DAMPa and the support part SPa may be prevented from being degraded.

FIGS. 9A to 9G are cross-sectional views illustrating some operations in a process of manufacturing a display panel according to some embodiments of the present disclosure.

Hereinafter, a configuration of the circuit layer DP-CL (see FIG. 6) and a method of forming the display element layer DP-OL (see FIG. 6) will be described with reference to FIGS. 9A to 9G.

Referring to FIG. 9A, a method of manufacturing the display panel DP of the present disclosure may include an operation of forming the data conductive layer DCL on the base substrate BS (see FIG. 6), an operation of forming a preliminary protective layer PPVX on the data conductive layer DCL, and an operation of forming a photoresist layer PVIA1 on the preliminary protective layer PPVX.

The display area DP-DA and the non-display area DP-NDA adjacent to the display area DP-DA may be defined in the base substrate BS.

The operation of forming the data conductive layer DCL includes an operation of depositing a metal layer and an operation of forming a data conductive layer by patterning the metal layer. The metal layer may include one of molybdenum (Mo), aluminum (Al), chromium (Cr), gold (Au), titanium (Ti), nickel (Ni), neodymium (Nd), and copper (Cu), or an alloy thereof.

The data conductive layer DCL may include the first connection electrode CNE1, the second connection electrode CNE2, and the first voltage wiring VW1.

The preliminary protective layer PPVX and the photoresist layer PVIA1 may be sequentially formed on the data conductive layer DCL.

As illustrated in FIGS. 9A and 9B, the method of manufacturing the display panel DP further includes an operation of patterning the photoresist layer PVIA1 to form a photoresist pattern PVIA2. The operation of patterning the photoresist layer PVIA1 includes an operation of arranging a mask HMS on the photoresist layer PVIA1 and performing a photo process using the mask HMS.

According to some embodiments of the present disclosure, the mask HMS may be a halftone mask. That is, the mask HMS may include an opening area MOA, a full-tone area FTA, and a half-tone area HTA. The opening area MOA is an area that transmits a light, and the full-tone area FTA is an area that blocks a light. The half-tone area HTA is an area that partially transmits a light. That is, light transmittance of the half-tone area HTA may be lower than light transmittance of the opening area MOA and higher than light transmittance of the full-tone area FTA.

In the opening area MOA, the photoresist layer PVIA1 is completely removed by a photo process, in the half-tone area HTA, the photoresist layer PVIA1 is partially removed by the photo process, and in the full-tone area FTA, the photoresist layer PVIA1 is not removed by the photo process.

First sub-contact portions SCNT1 and SCNTa, through which the preliminary protective layer PPVX is exposed, may be formed in the photoresist pattern PVIA2.

Referring to FIGS. 9B and 9C, the method of manufacturing the display panel DP may include an operation of etching the preliminary protective layer PPVX using the photoresist pattern PVIA2 to form the protective layer PVX. The photoresist pattern PVIA2 may be used as an etching mask of the preliminary protective layer PPVX. The process of etching the preliminary protective layer PPVX may be a dry etching process.

Second sub-contact portions SCNT2 and SCNTb may be formed on the protective layer PVX to correspond to the first sub-contact portions SCNT1 and SCNTa. The second contact hole CNT2 may be formed in the display area DP-DA by the first sub-contact portion SCNTa and the second sub-contact portion SCNTb, and the first contact portion CCNT1 may be formed in the contact area CCA by the first sub-contact portion SCNT1 and the second sub-contact portion SCNT2. In the display area DP-DA, the second contact hole CNT2 may expose the second connection electrode CNE2, and in the contact area CCA, the first contact portion CCNT1 may expose the first voltage wiring VW1.

In the method of manufacturing the display panel DP according to the present disclosure, since the photoresist pattern PVIA2 is used as an etching mask of the preliminary protective layer PPVX, the number of masks required for the method of manufacturing the display panel DP may be reduced. Thus, the process of manufacturing the display panel DP may be simplified.

Referring to FIG. 9D, the first electrode layer ELL1 may be formed on the photoresist pattern PVIA2. The first electrode layer ELL1 may include the first electrode EL1 of the light emitting element ED (see FIG. 6) located in the display area DP-DA and the second voltage wiring VW2 located in the non-display area DP-NDA.

The first electrode EL1 of the light emitting element ED is connected to the second connection electrode CNE2 through the second contact hole CNT2 in the display area DP-DA. The second voltage wiring VW2 is connected to the first voltage wiring VW1 through the first contact portion CCNT1 in the contact area CCA. The second voltage wiring VW2 may cover a side surface of the photoresist pattern PVIA2 defining the first sub-contact portion SCNT1 and a side surface of the protective layer PVX defining the second sub-contact portion SCNT2.

Referring to FIGS. 9D and 9E, the method of manufacturing the display panel DP includes an operation of forming the via insulating layer VIA by ashing a portion of the photoresist pattern PVIA2 exposed from the first electrode layer ELL1.

A thickness of a first portion of the photoresist pattern PVIA2 may be reduced by the ashing process, and a second portion of the photoresist pattern PVIA2 may be completely removed by the ashing process. The first portion of the photoresist pattern PVIA2 may remain at a position at which the support part SP (see FIG. 8B) and the dam part DAMP (see FIG. 8B) are to be formed in the non-display area DP-NDA, and thus the first support layer SL1 and the first dam layer DML1 (see FIG. 8B) may be formed.

The first support layer SL1 and the first dam layer DML1 may remain after the ashing process, and thus may have properties different from those of non-ashed portions. For example, the first support layer SL1 and the first dam layer DML1 may have higher moisture permeability than moisture permeability of the photoresist layer PVIA1 and the photoresist pattern PVIA2.

Referring to FIGS. 9E and 9F, the method of manufacturing the display panel DP includes an operation of forming the pixel defining layer PDL on the via insulating layer VIA and the first electrode layer ELL1. According to some embodiments of the present disclosure, the operation of forming the pixel defining layer PDL may include an operation of forming a preliminary pixel defining layer that covers the via insulating layer VIA and the first electrode layer ELL1 and an operation of patterning the preliminary pixel defining layer.

The pixel opening OH through which the first electrode EL1 is exposed and the second contact portion CCNT2 through which the second voltage wiring VW2 is exposed may be provided in the pixel defining layer PDL. The second contact portion CCNT2 may be located inside the first contact portion CCNT1. Thus, the pixel defining layer PDL may completely cover the tapered portion TP of the second voltage wiring VW2 in the contact area CCA.

The method of manufacturing the display panel DP may further include an operation of forming the second support layer SL2 covering the first support layer SL1 and the second dam layer DML2 (see FIG. 8B) covering the first dam layer DML1. The second support layer SL2 and the second dam layer DML2 may be formed simultaneously with the pixel defining layer PDL.

As illustrated in FIGS. 8B and 9F, according to some embodiments of the present disclosure, the second support layer SL2 may cover (completely cover) the upper surface SUS and the side surface SSS of the first support layer SL1. The width of the second support layer SL2 may be greater than the width of the first support layer SL1. The second dam layer DML2 may cover (completely cover) the upper surface DUS and the side surface DSS of the first dam layer DML1. The width of the second dam layer DML2 may be greater than the width of the first dam layer DML1.

According to some embodiments of the present disclosure, the second support layer SL2 and the second dam layer DML2 may have lower moisture permeability than that of the first support layer SL1 and the first dam layer DML1. Thus, the first support layer SL1 and the first dam layer DML1 having relatively high moisture permeability are completely covered by the second support layer SL2 and the second dam layer DML2 having relatively low moisture permeability, and thus moisture permeability preventing performance of the support part SP and the dam part DAMP may be prevented from being degraded.

Referring to FIG. 9G, the method of manufacturing a display panel DP according to the present disclosure includes an operation of forming the light emitting layer EML on the pixel defining layer PDL and an operation of forming a second electrode layer (or the second electrode) EL2 on the light emitting layer EML.

In the display area DP-DA, the light emitting layer EML may be located on the pixel defining layer PDL and a portion of the first electrode EL1 exposed by the pixel opening OH of the pixel defining layer PDL. In the display area DP-DA, the second electrode layer EL2 may be located on the light emitting layer EML, and in the contact area CCA, the second electrode layer EL2 may be located on the pixel defining layer PDL. The light emitting layer EML and the second electrode layer EL2 may not be arranged on the support part SP and the dam part DAMP.

The display module according to some embodiments may be applied to various electronic devices. The electronic device according to some embodiments may include the display module and may further include a module or a device having another additional function in addition to the display module.

FIG. 10 is a block diagram of an electronic device according to some embodiments of the present disclosure.

Referring to FIG. 10, an electronic device 10 according to some embodiments may include a display module 11, a processor 12, a memory 13, and a power module 14.

The processor 12 may control driving of the display module 11 and include at least one of a central processing unit (CPU), an application processor (AP), a graphic processing unit (GPU), a communication processor (CP), an image signal processor (ISP), or a controller.

Data information required for operations of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device and a power conversion module that converts power supplied by the power supply module to generate power required for the operation of the electronic device 10.

At least one of the components of the electronic device 10 may be included in the display module according to some embodiments. Further, some of individual modules functionally included inside one module may be included inside the display module, and the others thereof may be provided separately from the display module. For example, the display module 11 may be included in the display device, and the processor 12, the memory 13, and the power module 14 may be provided in the form of other devices in the electronic device 10 rather than the display device.

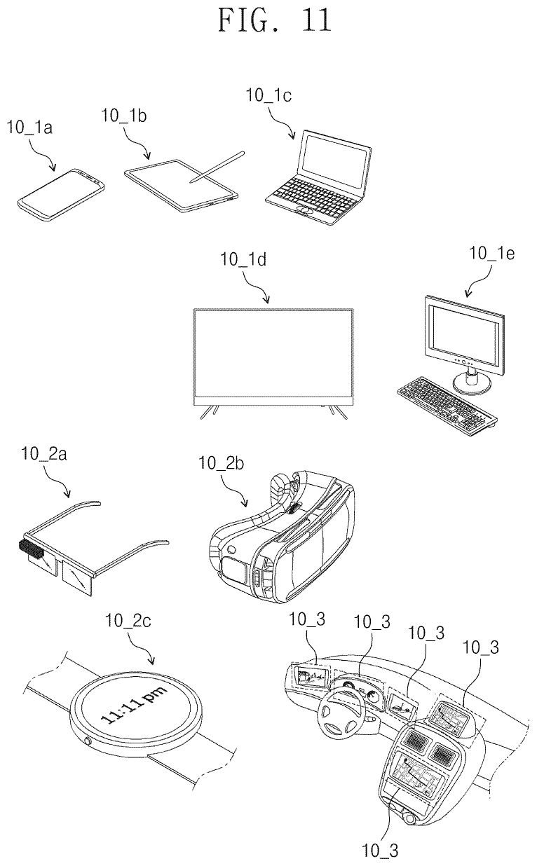

FIG. 11 is a schematic view illustrating electronic devices according to some embodiments.

Referring to FIG. 11, various electronic devices to which the display module is applied according to some embodiments may include an image display electronic device such as a smartphone 10_1a, a tablet PC 10_1b, a laptop computer 10_1c, a television (TV) 10_1d, and a desk monitor 10_1e, a wearable electronic device such as a smart glasses 10_2a, a head mounted display 10_2b, and a smart watch 10_2c, and a vehicle electronic device 10_3 such as an instrument panel, a center fascia, a center information display (CID) located on a dashboard, and a room mirror display of a vehicle.

According to some embodiments of the present disclosure, a tapered portion of a second voltage wiring is covered by a pixel defining layer, and thus a phenomenon in which moisture penetrates through the tapered portion and a phenomenon in which a profile of the tapered portion is collapsed due to a subsequent process may be prevented or reduced.

Further, in a dam part and a support part, a first dam layer and a first support layer are completely covered by a second dam layer and a second support layer having relatively low moisture permeability, and thus moisture permeation preventing performance of the dam part and the support part may be relatively improved.

Although the description has been made above with reference to aspects of some embodiments of the present disclosure, those skilled in the art may understand that the present disclosure may be variously modified and changed without departing from the spirit and the technical scope of the present disclosure described in the appended claims, and their equivalents.

Thus, the technical scope of embodiments according to the present disclosure is not limited to the detailed description of the specification but should be defined by the appended claims, and their equivalents.

What is claimed is:

1. A display panel comprising:
a base substrate including a display area and a non-display area adjacent to the display area;
a circuit layer including a data conductive layer, a protective layer on the data conductive layer, and a via insulating layer on the protective layer and on the base substrate; and
a display element layer including a first electrode layer, a pixel defining layer, a light emitting layer, and a second electrode layer and located on the circuit layer,
wherein the data conductive layer includes a first voltage wiring, and the first electrode layer includes a second voltage wiring connected to the first voltage wiring through a first contact portion provided through the protective layer and the via insulating layer in a contact area in the non-display area,
wherein a second contact portion, through which the second voltage wiring is exposed, is provided in the pixel defining layer, and the second electrode layer is connected to the second voltage wiring through the second contact portion, and
wherein a width of the second contact portion is smaller than a width of the first contact portion.

2. The display panel of claim 1, wherein the second voltage wiring includes a tapered portion configured to cover a side surface of the protective layer defining the first contact portion and a side surface of the via insulating layer defining the first contact portion, and
wherein the tapered portion is covered by the pixel defining layer.

3. The display panel of claim 1, wherein, in the contact area, the light emitting layer is between the pixel defining layer and the second electrode layer,
wherein, in the contact area, a third contact portion, through which the second voltage wiring is exposed, is provided in the light emitting layer, and
wherein the second electrode layer is connected to the second voltage wiring through the second contact portion and the third contact portion.

4. The display panel of claim 3, wherein a width of the third contact portion is smaller than the width of the second contact portion.

5. The display panel of claim 1, wherein the display panel further comprises:
a dam part having a closed loop shape in the non-display area; and
a support part in the non-display area to surround the dam part.

6. The display panel of claim 5, wherein the dam part includes:
a first dam layer on the protective layer; and
a second dam layer configured to cover the first dam layer on the protective layer, and
wherein the second dam layer covers an upper surface and side surfaces of the first dam layer.

7. The display panel of claim 6, wherein the second dam layer is made of a same material as the pixel defining layer, and
wherein a width of the second dam layer is greater than a width of the first dam layer.

8. The display panel of claim 5, wherein the support part includes:
a first support layer on the protective layer; and
a second support layer covering the first support layer, and
wherein the second support layer covers an upper surface and side surfaces of the first support layer.

9. The display panel of claim 8, wherein the second support layer is made of a same material as the pixel defining layer, and
wherein a width of the second support layer is greater than a width of the first support layer.

10. The display panel of claim 5, wherein the dam part includes a dam layer made of a same material as the pixel defining layer, and
wherein the support part includes a support layer made of the same material as the pixel defining layer.

11. The display panel of claim 5, wherein the data conductive layer includes a connection electrode connected to a transistor of each pixel, and
wherein the first electrode layer includes a first electrode connected to the connection electrode through an anode contact portion provided through the protective layer and the via insulating layer.

12. The display panel of claim 11, wherein a pixel opening, through which the first electrode is exposed, is provided in the pixel defining layer,
wherein the light emitting layer is on the first electrode exposed through the pixel opening, and
wherein the second electrode layer is on the light emitting layer.

13. A method of manufacturing a display panel, the method comprising:
forming a data conductive layer on a base substrate including a display area and a non-display area adjacent to the display area;
forming a preliminary protective layer on the data conductive layer;
forming a photoresist layer on the preliminary protective layer;
forming a photoresist pattern in which a first sub-contact portion is provided in a contact area in the non-display area by patterning the photoresist layer;
forming a protective layer in which a second sub-contact portion corresponding to the first sub-contact portion is provided by etching the preliminary protective layer using the photoresist pattern;
forming a first electrode layer on a portion of the photoresist pattern;
forming a via insulating layer by ashing a portion of the photoresist pattern exposed from the first electrode layer;
forming a pixel defining layer on the via insulating layer and the first electrode layer;
forming a light emitting layer on the pixel defining layer; and
forming a second electrode layer on the light emitting layer,
wherein the data conductive layer includes a first voltage wiring, and the first electrode layer includes a second voltage wiring connected to the first voltage wiring through a first contact portion including the first sub-contact portion and the second sub-contact portion,
wherein a second contact portion, through which the second voltage wiring is exposed, is provided in the pixel defining layer, and the second electrode layer is connected to the second voltage wiring through the second contact portion, and
wherein a width of the second contact portion is smaller than a width of the first contact portion.

14. The method of claim 13, wherein the second voltage wiring covers a side surface of the photoresist pattern defining the first sub-contact portion and a side surface of the protective layer defining the second sub-contact portion.

15. The method of claim 13, further comprising:
forming a dam part arranged in a closed loop shape in the non-display area and a support part in the non-display area to surround the dam part.

16. The method of claim 15, wherein the dam part includes:
a first dam layer on the protective layer; and
a second dam layer covering the first dam layer on the protective layer, and
wherein the second dam layer covers an upper surface and side surfaces of the first dam layer, and a width of the second dam layer is greater than a width of the first dam layer.

17. The method of claim 15, wherein the support part includes:
a first support layer on the protective layer; and
a second support layer covering the first support layer, and
wherein the second support layer covers an upper surface and side surfaces of the first support layer, and a width of the second support layer is greater than a width of the first support layer.

18. The method of claim 13, wherein the photoresist pattern is formed by patterning the photoresist layer using a mask, and
wherein the mask includes an opening area, a full-tone area, and a half-tone area.

19. An electronic device comprising:
a display module including a display panel; and
a processor configured to control driving of the display module,
wherein the display panel includes:
a base substrate including a display area and a non-display area adjacent to the display area;
a circuit layer including a data conductive layer, a protective layer on the data conductive layer, and a via insulating layer on the protective layer and on the base substrate; and
a display element layer including a first electrode layer, a pixel defining layer, a light emitting layer, and a second electrode layer and on the circuit layer,
wherein the data conductive layer includes a first voltage wiring, and the first electrode layer includes a second voltage wiring connected to the first voltage wiring through a first contact portion provided through the protective layer and the via insulating layer in a contact area in the non-display area,
wherein a second contact portion, through which the second voltage wiring is exposed, is provided in the pixel defining layer, and the second electrode layer is connected to the second voltage wiring through the second contact portion, and
wherein a width of the second contact portion is smaller than a width of the first contact portion.

20. The electronic device of claim 19, wherein the second voltage wiring includes a tapered portion configured to cover a side surface of the protective layer and a side surface of the via insulating layer defining the first contact portion, and
wherein the tapered portion is covered by the pixel defining layer.
